(19) United States
(12) Patent Application Publication
(10) Pub. No.: US 2020/0174207 A1
(43) Pub. Date: Jun. 4, 2020

(54) ELECTRO-OPTICAL DEVICE

(71) Applicant: Dust Photonics Ltd., Modiin (IL)

(72) Inventors: Moti Cabessa, Netanya (IL); Ben Rubovitch, Modiin (IL); Amir Geron, Modiin (IL); Jacob Hasharoni, Srigim (IL)

(21) Appl. No.: 16/785,685

(22) Filed: Feb. 10, 2020

Related U.S. Application Data
(63) Continuation-in-part of application No. 15/790,860, filed on Oct. 23, 2017.
(60) Provisional application No. 62/803,512, filed on Feb. 10, 2019.

(51) Int. Cl. G02B 6/43; G02B 6/42

(52) U.S. Cl. CPC G02B 6/43; H01S 5/183; G02B 6/4256; G02B 6/4203

(57) ABSTRACT

An electro-optic unit that may include a substrate, multiple optical engines, multiple electro-optic sub-units and optical conduits. Each optical engine may include one or more mechanical housings, each mechanical housing may include a group of lenses. Each electro-optic sub-unit is selected out of (a) a transmit electro-optic sub-unit that may include a group of lasers and a group of at least one laser driver, (b) a receive electro-optic sub-unit that may include a group of detectors and a group of at least one reception circuits; and (c) a hybrid electro-optic sub-unit that may include a receive portion and a transmit portion; wherein the transmit portion may include a sub-group of lasers and a sub-group of at least one laser driver; wherein the receive portion may include a sub-group of detectors and a sub-group of at least one reception circuits. At least two electro-optic sub-units are positioned between the substrate and at least two electro-optic sub-units that are associated with the at least two electro-optic sub-units. The at least two electro-optic sub-units are not positioned one above the other.

### CROSS REFERENCE

This applications claims priority from U.S. provisional patent 62/803512 filing date Feb. 10, 2019 which is incorporated herein by reference.

This application is a Continuation In Part of U.S. patent application Ser. No. 15/790,860 filing date Oct. 20, 2017 which is incorporated herein by reference.

### BACKGROUND

Transceivers used in datacom, telecom and high-performance computing carry out the electrical-to-optical data conversion using an optical engine assembled within the transceiver housing. The functionality of such an engine is to convert the high-speed electrical signal to a corresponding high-speed optical signal using a laser source. Typically, vertical-cavity surface-emitting laser (VCSEL) are used for multimode devices while edge emitting lasers are commonly used for single mode applications. Coupling of the optical signal to the fiber is also done by the optical engine using a set of lenses and folding mirrors. A similar optical engine exists also for the reverse operation, that of optical-to-electrical signal conversion and in this case, vertically illuminated p-i-n photodiodes (PD) are typically used. The VCSEL and PD optoelectronic chips are driven by a laser driver (LD) and trans-impedance amplifier (TIA), respectively. These electronics chips are also considered part of the optical engine.

The number of data channels in each optical engine varies and depends on the total bandwidth and the lane data rate. Typical lane count is 1 or 4 but may very well extend to larger numbers if space considerations allow it.

Transceivers used for datacom and telecom applications utilize several optical engines; the actual number depends on the transceiver bandwidth and on the number of high-speed lanes that a single device can handle.

The limiting factor is thus the physical size of the optical engine that determines how many can be packaged within the transceiver housing.

### SUMMARY

There may be provided a an electro-optic unit that may include a substrate, multiple optical engines, multiple electro-optic sub-units and optical conduits. Each optical engine may include one or more mechanical housings, each mechanical housing may include a group of lenses. Each electro-optic sub-unit is selected out of (a) a transmit electro-optic sub-unit that may include a group of lasers and a group of at least one laser driver, (b) a receive electro-optic sub-unit that may include a group of detectors and a group of at least one reception circuits; and (c) a hybrid electro-optic sub-unit that may include a receive portion and a transmit portion; wherein the transmit portion may include a sub-group of lasers and a sub-group of at least one laser driver; wherein the receive portion may include a sub-group of detectors and a sub-group of at least one reception circuits. At least two electro-optic sub-units are positioned between the substrate and at least two electro-optic sub-units that are associated with the at least two electro-optic sub-units. The at least two electro-optic sub-units are not positioned one above the other.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates an example of a system;

FIG. 2 illustrates a transmit optical path from a transmitting optoelectrical chip to an optical fiber;

FIG. 3 illustrates a receive optical path o an optical fiber to a receive optoeletrical chip;

FIGS. 4A-4B are examples of a top view and a bottom view of an optical mount of an electrical coupler;

FIGS. 5A-5B are examples of a top view and a bottom view of an optical mount of a fiber ferrule;

FIG. 6A illustrates an example of a clip;

FIG. 6B is an example of a clip that holds the optical mount and the fiber ferrule;

FIG. 7 is an example of a method;

FIG. 8 illustrates an optical coupler;

FIG. 9 illustrates an optical coupler;

FIG. 10 illustrates two network switches;

FIG. 11A illustrates an example of a device;

FIG. 11B illustrates an example of a device;

FIG. 12 illustrates an example of a device;

FIG. 13A illustrates an example of a device;

FIG. 13B illustrates an example of a device;

FIG. 14A illustrates an example of a device; and

FIG. 14B illustrates an example of a device.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a module capable of executing the method.

Any reference in the specification to a module should be applied mutatis mutandis to a method that may be executed by the module.

The term “substantially”—unless stated otherwise may refer to a deviation of few percent (for example—deviation of less than ten percent or less than 20 percent).

Any combination of any module, chip, circuit, or component listed in any of the figures, any part of the specification and/or any claims may be provided. Especially any combination of any claimed feature may be provided.

There may be provided an electro-optic unit that may include a substrate, multiple optical engines, multiple electro-optic sub-units and optical conduits.

Each optical engine may include one or more mechanical housings, each mechanical housing may include a group of lenses.

Each electro-optic sub-unit is selected out of three types—(a) a transmit electro-optic sub-unit that may include a group of lasers and a group of at least one laser driver, (b) a receive electro-optic sub-unit that may include a group of detectors and a group of at least one reception circuits; and (c) a hybrid electro-optic sub-unit that may include a receive portion and a transmit portion; wherein the transmit portion may include a sub-group of lasers and a sub-group of at least one laser driver; wherein the receive portion may include a sub-group of detectors and a sub-group of at least one reception circuits.

At least two electro-optic sub-units are positioned between the substrate and at least two electro-optic sub-units that are associated with the at least two electro-optic sub-units. The at least two electro-optic sub-units are not positioned one above the other.

The electro-optic unit may be compact and multiple electro-optic units may be positioned in compact spaces—thus providing multiple channel connectivity between devices even within systems that allocated only small spaces for connectors, switches and other intermediate units.

By selecting the one or more types of the electro-optic sub-unit—the role of the electro-optic unit is determined. For example an electro-optic unit that is a transceiver includes a hybrid electro-optic sub-unit and/or a combination of at least two types of electro-optic sub-unit. If all electro-optic sub-units of an electro-optic unit are receive electro-optic sub-unit then the electro-optic unit is a receiver. If all electro-optic sub-units of an electro-optic unit are transmit electro-optic sub-unit then the electro-optic unit is a transmitter.

For simplicity of explanation, some of the following figures assume that the electro-optic unit is a transceiver that includes receive electro-optic sub-units and transmit electro-optic sub-units.

It should be noted that any combination of any types of electro-optic sub-unit may be provided. The relationship between the number of different types of electro-optic sub-unit may vary from those illustrated in the following figures. For example—in a transceiver, the number of receive electro-optic sub-units may be the same as the number of transmit electro-optic sub-units, may be smaller than the number of the transmit electro-optic sub-units or may exceed the number of the transmit electro-optic sub-units. The same applied to the number of hybrid electro-optic sub-unit.

The at least two electro-optic sub-units may be all or some of the multiple electro-optic sub-units. In case that they are all of the multiple electro-optic units then neither one of the electro-optic sub-units are positioned above each other. In case that they are some of the electro-optic units the two or more electro-optic sub-units may be positioned above each other.

At least two electro-optic sub-units may be positioned at substantially a same distance from the substrate.

The at least two electro-optic sub-units may include four electro-optic sub-units, less than four electro-optic sub-units or more than four electro-optic sub-units.

The at least two electro-optic sub-units may be arranged in any manner—for example in an ordered grid, an unordered grid, a line, a column, a circle. For example—they may be arranged as a grid of two lines by two columns (“two by two”) electro-optic sub-units.

The grid may include two electro-optic sub-units that are transmit electro-optic sub-units and two electro-optic sub-units that are receive electro-optic sub-units. Any other combinations of one or more types of electro-optic sub-unit may be provided.

Each optical engine may be or may include an optical coupler. Non-limiting examples of optical engines are illustrated in U.S. patent application Ser. No. 15/790,860. An optical engine may include a first portion of the optical coupler illustrated in U.S. patent application Ser. No. 15/790,860 and/or may include a second portion of the optical coupler illustrated in U.S. patent application Ser. No. 15/790,860.

An optical engine may include a mechanical housing.

The optical coupler may include (a) a first mechanical housing that belongs to a first portion of the optical coupler, and (b) a second mechanical housing that belongs to a second portion of the optical coupler.

The first portion of the optical coupler may include an optical cable interface for receiving a group of optical conduits and three contact elements. Each contact element may have a spherical surface. The optical cable interface and the three contact elements may belong to the first mechanical housing or may not belong to the first mechanical housing.

The second portion of the optical coupler may include three elongated grooves.

Each group of lasers may include eight lasers, more than eight lasers or fewer than eight lasers.

Each group of detectors may include eight detectors, more than eight detectors or fewer than eight detectors.

The substrate may be compact—for example a length of the substrate may range between 50 and 60 millimeters (for example be 55 millimeters long), and a width of the substrate ranges between 14 and 19 millimeters (for example be 16.5 millimeters wide).

A length of an optical engine may range between 2-10 millimeters—for example be about 8.5 millimeters. A width of the optical engine may range between 1-6 millimeters—for example be about 4.6 millimeters.

There may be provided a device that belongs to a high-speed optical communication systems, such as 400 Gigabit-per-second (400 G) transceivers. More specifically, the present invention provides a method that allows optical connectivity between 400 G modules and legacy modules such as 100 G devices given the limited space available.

In data center applications, there are network switches of different generations with electrical trace speed that matches the technology of the switch. For example, 12.8 Tb/s network switches utilize electrical interfaces that can run up to 50 Gb/s per trace while 6.4T switches use 25 G electrical interfaces. Both switch generations may be found in a single data center and thus, the optical transceiver connecting them must be able to perform the required data rate conversion.

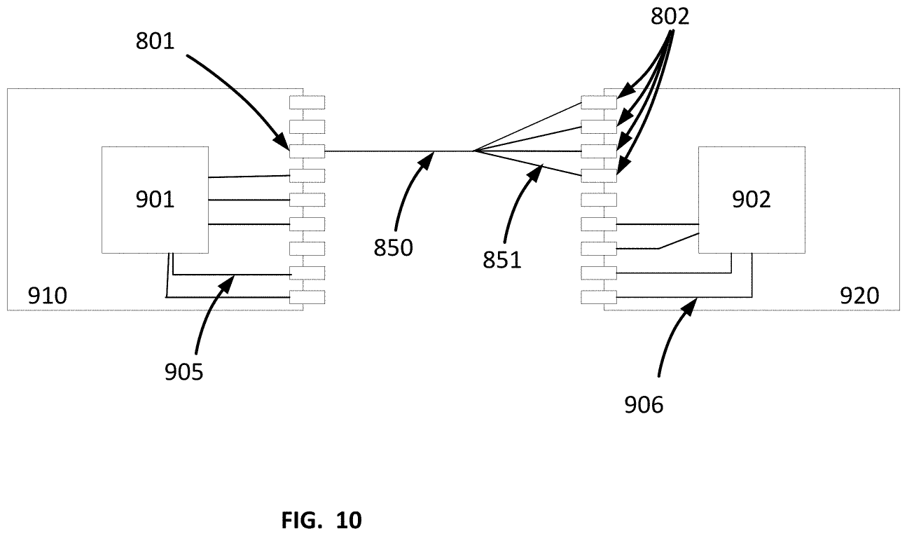

A typical situation is shown in FIG. 10 in which network switch 910 with switch ASIC 901 is connected via transceiver 801 and fiber 850 to network switch 920 with switch ASIC 902 via transceivers 802. The switch ASICs 901 and 902 are connected to the pluggable transceivers 801 and 802 via electrical traces 905 and 905 which are metal traces on the PCB. For the purpose of this example, switch 901 has higher bandwidth and operates at double the electrical trace speed of switch 902. The bandwidth of transceiver 801 can be for example 400 Gb/s corresponding to an electrical input of 8 lanes, each running at 50 Gb/s. The bandwidth of transceivers 802 can be for example 100 Gb/s with 4 input traces each running at 25 Gb/s.

The total bandwidth handled by transceiver 801 cannot be routed via fiber 850 directly to either one of the transceivers 802 on switch 902 as they operate at lower lane rate and thus, four devices are required to receive the data from transceiver 801. Fiber 850 is therefore split into 4 sub fibers 851 where each of these fibers carries 100 Gb/s of data to one of the transceivers 802.

Transceiver 801 is thus a unique device that handles the transition from 8 lanes at 50 Gb/s into 16 lanes at 25 Gb/s. While this transition is obvious, the method by which such transceivers are built is not trivial due to significant space limitations.

Transceivers such as 801 and 802 can be based on the quad small form-factor pluggable (QSFP) design; this module is the most popular form-factor in the data center. However, other form-factors may be used as well, for example the octal small format pluggable (OSFP). The front panel of the switch chassis is built specifically to accommodate about 30 such pluggable devices. Due to space limitations, these devices are dense with limited freedom for placement of the optical and electronic chips required for the transceiver operation.

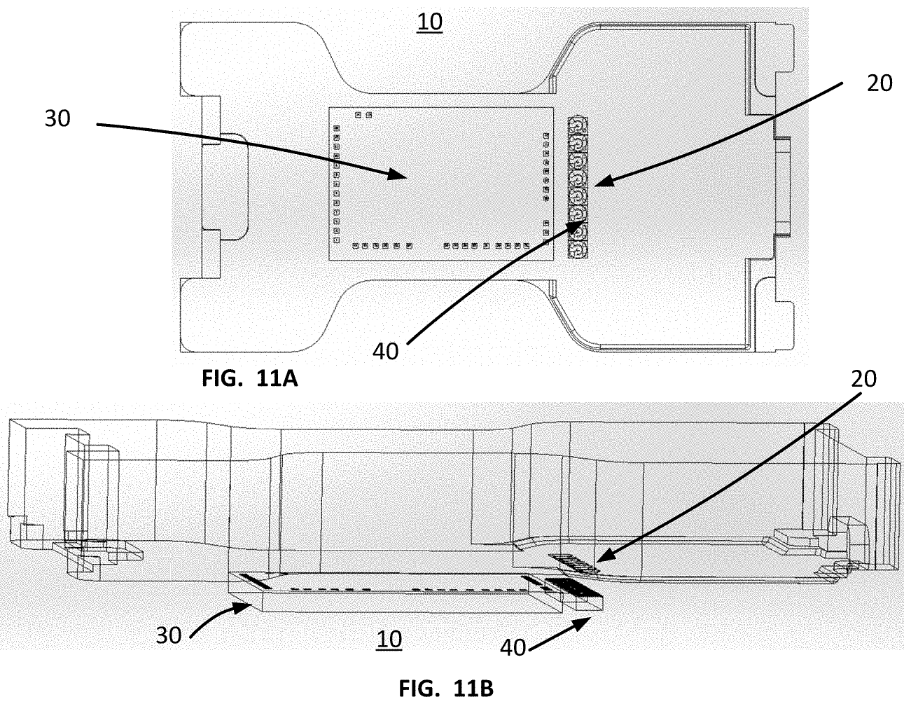

The design of an optical engine that will enable the dense layout required for a high lane count device is shown in FIGS. 11A and 11B. This optical engine can handle 8 lanes with the VCSEL driver or TIA located underneath the mechanical housing to optimize space utilization. As can be seen from FIG. 11A, optical engine 10 is a mechanical housing that houses 8 micro-lenses 20. It can be appreciated that at least 8 channels are required in a single optical engine in order to meet the space limitations of the transceiver 801. FIG. 11A is a top view of the device and the laser driver/TIA 30 can be seen adjacent to VCSEL or PD array 40 that has 8 elements. Driver 30 is connected to VCSEL/PD 40 via wirebonds. In FIG. 11B we show the same optical engine 10 from the side; the placement of the driver and laser/PD array is clearly seen to be under the lens mount. It can be appreciated from FIGS. 11A and 11B that the compact design of optical engine 10 is a key element in the layout and architecture of transceiver 801. Placement of larger optical engine or of lower lane count devices will lead to a failure in achieving the required lane density.

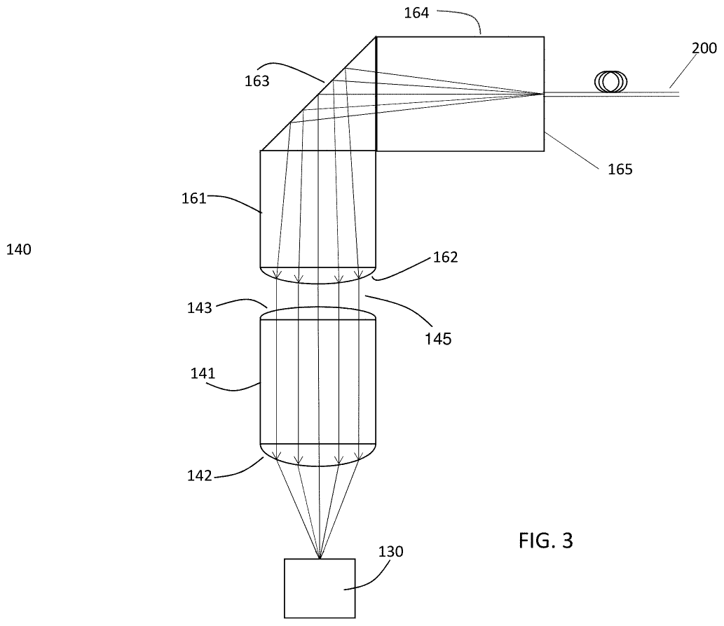

A general layout of transceiver 801 which is capable of connecting a high-speed switch port to several lower speed switch ports is shown in FIG. 3. All elements are mounted on a printed circuit board (PCB) 810 that fits in size to the transceiver housing. In this example, there are four optical engines that handle the electrical to optical (transmit) and optical to electrical (receive) functions.

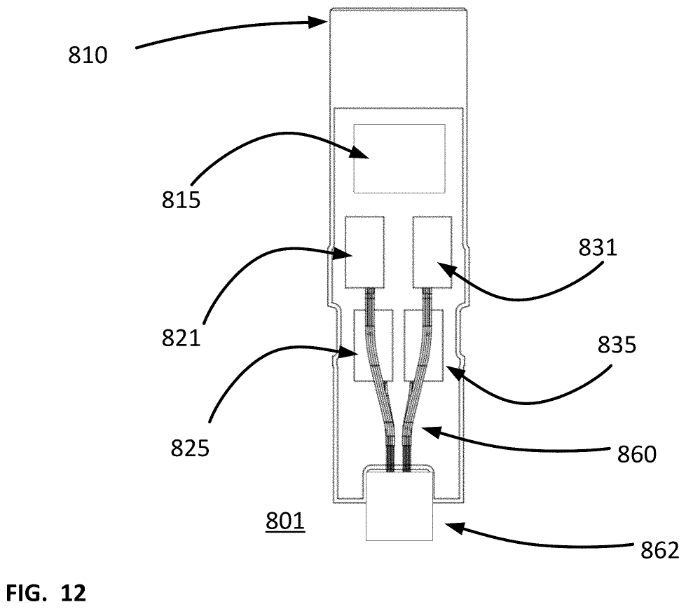

These are engines 821 and 825 for transmit and 831 and 835 for receive. Both devices 821 and 825 are identical as are devices 831 and 835. Signal conditioning and clock data recovery are carried out via a chip 815 that may be a DSP or other digital processor. Fiber ribbons 860 from each optical engine enables connection to output fiber 850 via fiber ferrule 862. It can be appreciated from FIG. 12 that the optical engines must be both: i) handle 8 lanes of optical—electrical conversion and ii) sufficiently narrow in order to fit within the transceiver housing. Overall, the device must accommodate the DSP 815, optical engines and fiber ferrule 862.

In the drawings shown here, it is assumed that each optical engine can handle 8 lanes; similarly, optical engines with 12, 16 or any other combination of optical—electrical lanes can be used as long as the devices fit in the transceiver housing.

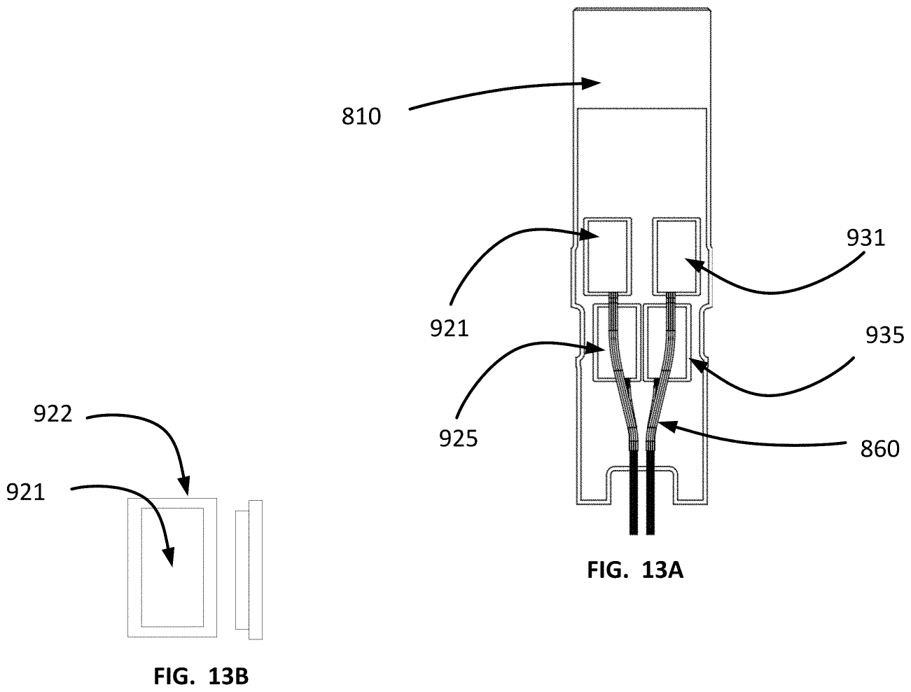

FIGS. 13A and 13B illustrate a second assembly and layout option in which the optical engine 921 is assembled on a carrier chip 922. FIG. 13A shows the whole device while FIG. 13B shows a single optical engine on its carrier both from above and from the side. This carrier may be an organic, ceramic or any other suitable material. The optical engine 921 is glued to carrier 922 with the benefit of allowing a separate assembly and test flow for the optical engine which is separate from the transceiver assembly. Connection of the optical engine 921 to the fiber ribbon 160 can be carried out either during carrier assembly or during assembly on PCB 810.

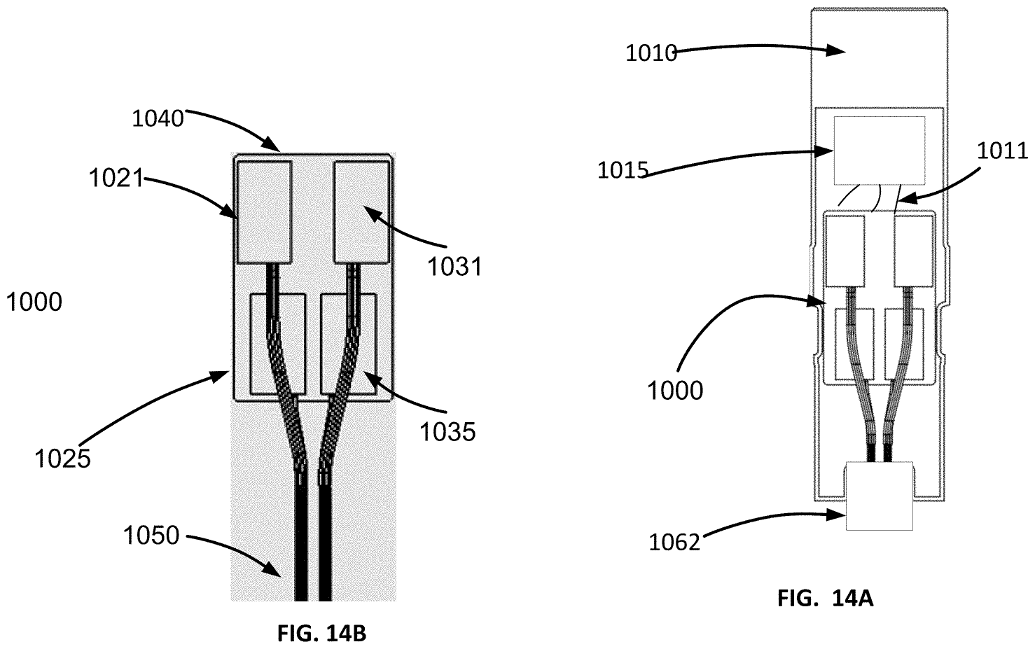

A third assembly option is shown in FIGS. 14A and 14B. All of the optical engines are assembled on a single carrier 1000. A detailed view is given in FIG. 14B showing the four optical engines 1021, 1025, 1031 and 1035 assembled onto carrier 1040 with fiber ribbons 1050 connecting each optical engine to a fiber ferrule 1062. The assembly shown in FIGS. 14A and 14B has the advantage that all four optical engines can be mounted and tested on a single substrate thus optimizing production flow and efficiency. The sub-assembly 1000 is than glued on PCB 1010. Electrical connection to the host DSP 1015 including the high-speed RF lines is done using wire bonds 1011. Metal traces on the PCB can be used as well to connect to assembly 1000; in this case, solder bumps will be used to connect the carrier 1040 to the PCB.

Each one of engines 821, 825, 831, 835, 921, 925, 931, 235, 1021, 1025, 1031 and 1035 may include an optical engine such as optical engine 10 of FIGS. 11A and 11B.

There may be provided a method for operating the device—for example by transmitting and/or receiving information using any of the devices and/or systems illustrated in the application.

Optical Coupler

Passive fiber alignment is much more suited for volume production of optical devices as the process can be carried out with fully automated pick-and-place machines using pre-defined alignment marks to locate the coupling elements. The accuracy of passive alignment depends on the assembly machine accuracy and repeatability as well as on the accuracy of the alignment mark. Passive alignment can lead to significant reduction of the device packaging cost due to the lower operation cost, higher machine throughput and since yields tend to be higher with passive, machine-based alignment.

Multimode optical links employ vertically emitting optoelectronic chips namely, vertical-cavity surface-emitting laser (VCSEL) and vertically illuminated p-i-n PDs. These devices are difficult to align as the lens needs to be mounted above the device and a right angle turn of the fiber is required in order to fit the coupling optics within the transceiver housing. Efficient fiber coupling is possible if all optical elements are co-located on an axis given the 6 degrees of freedom. With active alignment, this can be accomplished in a straight-forward way by moving the fiber and/or lens both lateral and angular along the XYZ axes until good coupling is achieved. With passive alignment, the situation is more complicated since mounting the lens and fiber has no feedback and a method must be devised to avoid tilt and rotation.

The following description of the embodiment is based on an optical transceiver for optical communications. However, the invention is valid for other applications as well in which surface emitting laser and surface illuminated PD are being used.

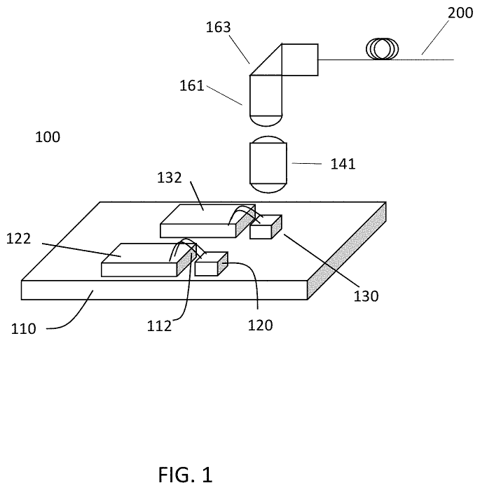

Referring to FIG. 1, the optical transceiver 100 has a substrate 110, VCSEL 120 and PD 130.

The VCSEL is connected via wire bond 112 to laser driver chip 122 and the PD is connected to a trans-impedance amplifier (TIA) 132. A first lens 141 is mounted above VCSEL 120 and above PD 130. The lens 141 may be of any shape such as bi-convex, plano-convex or concave. A second lens 161 is mounted above lens 141 with one curved surface and a right-angle prism 163 used to fold the light by 90° so that the optical axis is collinear with the fiber 200.

VCSEL 120 and PD 130 may be single elements or in array format, typically four elements are used in communication devices, but any other number common in the industry may be used. The lens 141 may be a part of an array with either the same number of optical apertures or higher. Substrate 110 can be a printed circuit board (PCB) or any other suitable electronic substrate. VCSEL driver chip 122, TIA 132, VCSEL 120 and PD 130 are glued onto the substrate 110 using thermal epoxy glue. The distance between the driver chips and the optical chips is very short to enable short length of wire bond 112. The short wire length is critical for obtaining high frequency operation of the laser and photodiodes.

In one embodiment of this invention, the lens array is fabricated such that it has similar dimensions to both VCSEL 120 and PD 130. Two such lenses are assembled, one above the VCSEL and the other above the PD. Using separate lenses has the advantage that the relative orientation of both VCSEL 120 and PD 130 is not relevant. Fiber alignment is carried out independently for each one. The lens array can be aligned above the laser and photodiode arrays using standard pick-and-place machine. Alignment features on both the lens and the laser or PD are used to facilitate accurate positioning of the lens array. A second lens 142 is located above first lens 141 to assist in the light coupling to or from fiber 200.

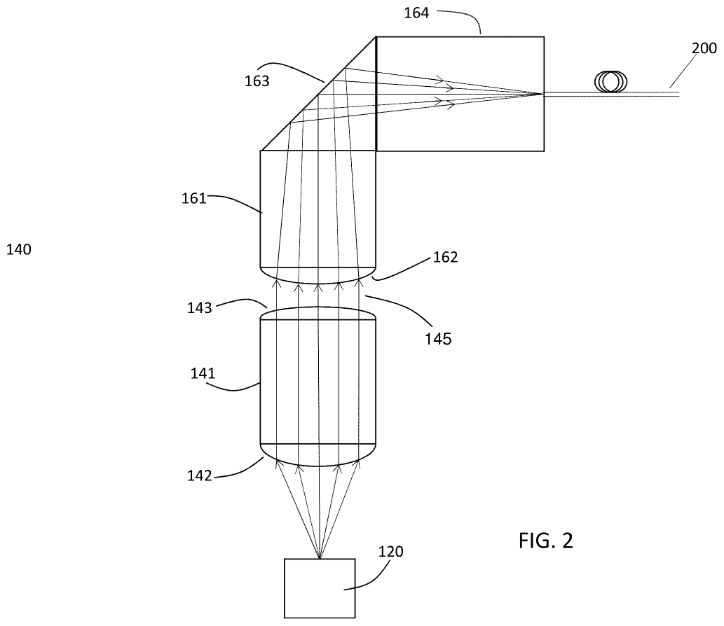

FIGS. 2 and 3 illustrates the optical system 140 used for the passive assembly. It is built from two lenses 141 and 161 that function as one optical system. The lens 140 is used for both coupling tasks, VCSEL-to-fiber and fiber-to-PD. Even though the optical path is different in both cases, the design of lens 140 is capable to support both.

In FIG. 2 the optical path from the VCSEL 120 to the fiber 200 is shown; optical surface 142 collects light emitted from VCSEL 120. The surface 142 is designed to collect all the emitted light using an aspherical profile and NA that covers the entire angular distribution of the laser. Minimizing the sensitivity for alignment errors is achieved by designing the optical system as a multi-lens relay that allows for the beam to reach the fiber 200 with minimal distortions due to assembly errors. This task is achieved by broadening the beam to about 200 μm and collimating the light collected using surface 142 and surface 143. The homogenous energy distribution within the broadened beam exhibits minimal sensitivity to misalignment and allows to compensate for tilts and lateral shifts that are inherent to the assembly.

An air gap 145 is located between lens 141 and lens 163; its thickness is determined by the size of the mechanical system used to align and join the two lenses. As the light beam is also collimated in this air space, it shows minimal sensitivity for angular and lateral misalignment between the two elements.

Optical surface 162 collects the light and directs it to the hypotenuse of right angle prism 163. The combined action of surfaces 162, 163 and optical slab 164 is to focus the light tightly on the entry aperture of fiber 200. An underfill launch condition is required to minimize mode excitation achieved by a tightly focused spot on the center of the fiber aperture. Surface 163 may be planner or parabolic or any freeform polynomial surface as required by the optical performance.

FIG. 3 illustrates the optical path from the fiber 200 to PD 130. Light from the fiber 200 is emitted with a NA typical of multimode fibers. Optical surfaces 162, 163 and slab 164 collect the light and shape it such that the beam in air space 145 is fully collimated. Lens 141 focused the light beam onto the PD aperture using optical surface 142. At modulation frequencies of 50 Gb/s using pulse amplitude modulation of 4 or 8 levels, the PD aperture must be minimized to sub-30 μm diameter to maintain the capacitance low enough. The negative magnification required to couple light from the 50 μm fiber core to the PD is the most critical aspect of this invention and obtained using the combined effect of the beam shape and the aspherical profile of surface 142.

Lens system 140 can be fabricated from glass plastic or any suitable material with high transparency at the VCSEL wavelength of 850 nm. If the material is plastic, injection molding may be used to further reduce the device cost. Optical elements 141 and 161 are embedded within a mechanical structure designed to align the lenses passively with respect to the optoelectronic chips or the fibers.

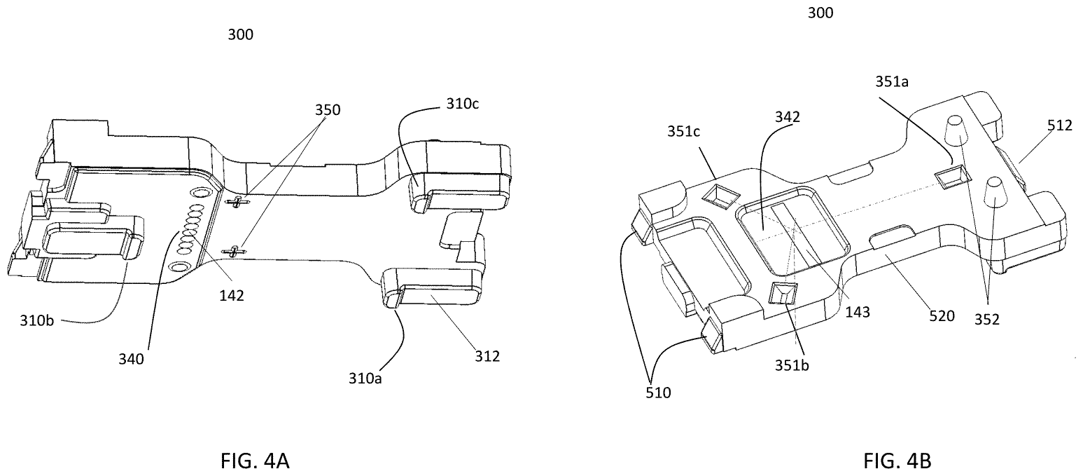

FIGS. 4A and 4B illustrate an optical mount 300 in which lens 141 is enclosed as part of lens array 340.

The bottom side is shown in FIG. 4A with an eight-element lens array 340 where each optical element corresponds to optical lens 141 shown in FIGS. 2 and 3. Typical arrays used in devices for optical communication have four elements per array. Increasing the number of optical lenses 141 to eight, as in this invention, allows freedom to use driver chips from different vendors where the location of the wire bond 112 pads may vary between chips. With a large lens array 340, any combination of VCSEL 120 and driver chip 122 (or PD 130 and TIA chip 132) may be realized even if it implies that the location of the VCSEL (PD) array is shifted laterally with each chip combination.

The optical mount 300 is assembled on the substrate 110 using three legs 310 positioned such that both driver chip 122 (132) and optoelectronic chip 120 (130) can be accommodated in the space created between substrate 110 and optical mount 300. Attachment to the substrate is carried out using a thermal curing epoxy adhesive dispensed on surface 312. The height difference between leg 310 and surface 312 determines the amount of glue used. The adhesion of the epoxy to surface 312 is enhanced by specific treatment of the surface. Accurate alignment of the lens array 340 with respect to VCSEL array 120 or PD array 130 is carried out with a pick-and-place machine using alignment marks 350 whose position with respect to optical lens array 340 is known.

The top side of optical mount 300 is shown in FIG. 4B.

Optical lens array 340 is in a recess 342 with optical surfaces 143. The depth of the recess is determined by the required thickness for lens 141. Rough alignment of optical mount 300 with the fiber ferrule 400 is done using guide pins 352. The three V-shaped slots 351 are part of the accurate alignment mechanism described below for assembly of fiber ferrule 400 on mount 300. The slots 351 are oriented at 120° with respect to each other thus defining a geometrical center.

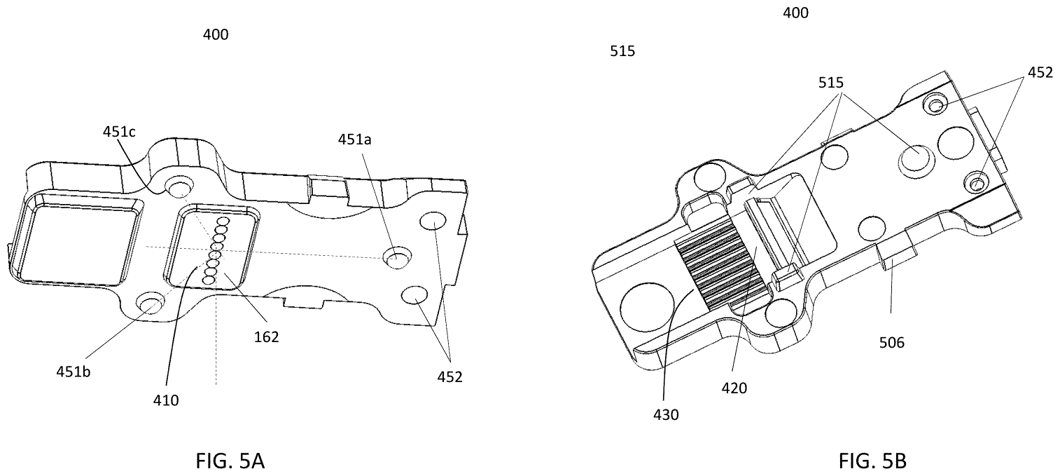

With respect to FIG. 5A, holes 452 allow for guide pins 352 to perform rough mating of optical mount 300 with ferrule 400. Optical lens array 410 has also eight elements each one with lens 162. Accurate alignment of the fiber ferrule 400 on the optical mount 300 is enabled with three balls 451 that self-align onto slots 351 located on the mount. This design overlaps the optical axis of lens array 410 and the optical axis of lens array 340 with the geometric center of the three V-shaped slots 351. The geometrical center location is fully defined and thus its position is fixed even in the case of thermal expansion or mechanical stress. Using V-shaped slots allows to constrain the degrees of freedom. Each slot constrains two degrees of freedom (one per wall) totaling in all six degrees being locked. The ball-slot system allows for alignment of ferrule 400 on mount 300 with sub-micron accuracy.

When the three balls 451a, 451b and 451c are aligned with three grooves 351a, 352b and 352c then the first and second lens arrays are aligned with each other. Furthermore, the first and second lens arrays are located within a center of stability—which is stable (or at least substantially stable) even when the optical coupled device undergoes thermal variations. The first and second lens arrays are relatively stable and thus do not misalign under thermal and/or mechanical stress because the intersection of imaginary longitudinal axes of the three grooves (and an intersection of the three balls) falls on the optical axis of both the first and second optical lens arrays respectively.

In FIG. 5B the top side of the ferrule 400 is shown with a V-groove array 430 that allows for accurate positioning of the fiber ribbon with respect to the optical axis. A fiber ribbon or separate fibers are placed on the v-groove. The fibers terminate on optical surface 165 within enclosure 420 that contains the right-angle prism 163 and lens 162. A drop of optical grade adhesive is used to fix the fibers in place.

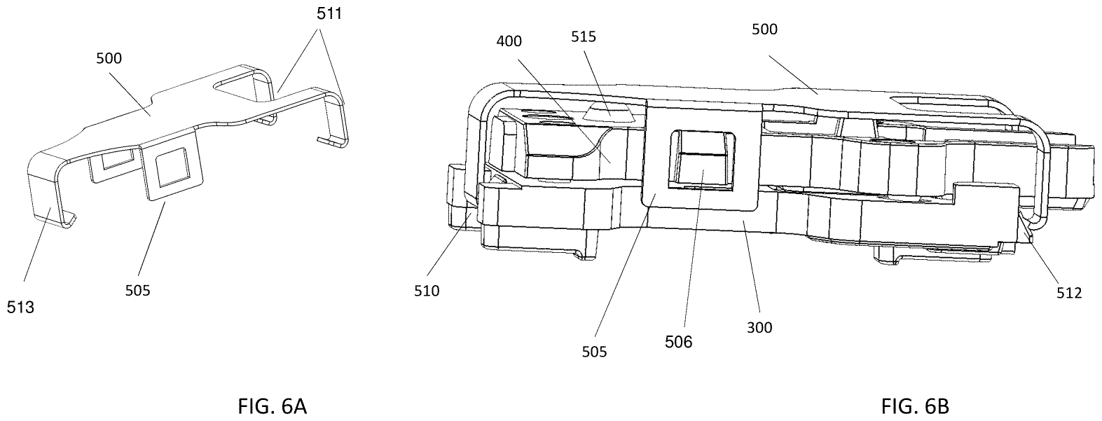

Attachment of ferrule 400 on mount 300 is carried out using a clip 500 shown in FIG. 6A. The clip may be constructed from metal or other suitable material. It is designed to couple the two optical elements without causing strain. Initial attachment of the clip 500 is done using flexible flange 505 that clips onto slab 506. The reason for this preliminary step is to provide easy assembly for the operator. Mount 300 is thus designed with a narrow waist 520 that allows for clipping of flange 505 on slab 506. Stress-free final attachment of the clip is enabled with the slabs 510 and 512 located on mount 300. Flexible flange 513 and 511 located on clip 500 attach on the three slabs providing the full attachment as needed. To distribute the stress originating by clip 500, three studs 515 located on the top surface of ferrule 400 are used.

The assembled device is shown in FIG. 6B. Because of its simplicity, the clip is snapped-on using either manual or automatic placement.

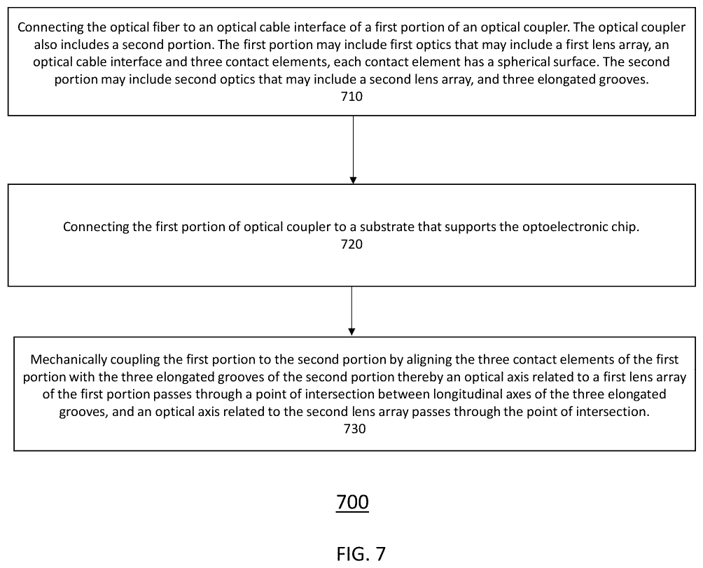

FIG. 7 illustrates an example of method 700.

Method 700 may include the following steps:

a. Connecting the optical fiber to an optical cable interface of a first portion of an optical coupler. The optical coupler also includes a second portion. The first portion may include first optics that may include a first lens array, an optical cable interface and three contact elements, each contact element has a spherical surface. The second portion may include second optics that may include a second lens array, and three elongated grooves. 710. The first portion may be fiber ferrule 400. The second portion may be optical mount 300.

b. Connecting the first portion of optical coupler to a substrate that supports the optoelectronic chips. 720.

c. Mechanically coupling the first portion to the second portion by aligning the three contact elements of the first portion with the three elongated grooves of the second portion thereby an optical axis related to a first lens array of the first portion passes through a point of intersection between longitudinal axes of the three elongated grooves, and an optical axis related to the second lens array passes through the point of intersection. 730.

Method 700 is a passive method in the sense that successful alignment may be achieved when following steps 710, 720 and 730—and there is no need to monitor the alignment process by activating the electro-optical circuits and any other circuit. It is noted that method 700 may include actively monitoring the alignment—but this is not necessarily so.

The number of optical paths may equal to the number of optical couplers or may differ from the number of optical couplers. An optical path is associated with a single fiber and/or a single laser. A single optical coupler may be placed over an array of photodiodes. A single optical coupler may be placed over an array of lasers. A single optical coupler may be placed over a combination of (i) one or more photodiodes, and (ii) one or more lasers.

The same optical coupler may be used for both receive path and transmit path.

A single optical coupler may be positioned in both (a) one or more transmit optical paths and (b) one or more receive optical paths. Alternatively, a separate optical coupler may be positioned in one or more transmit optical paths and a separate optical coupler may be positioned in one or more receive optical paths.

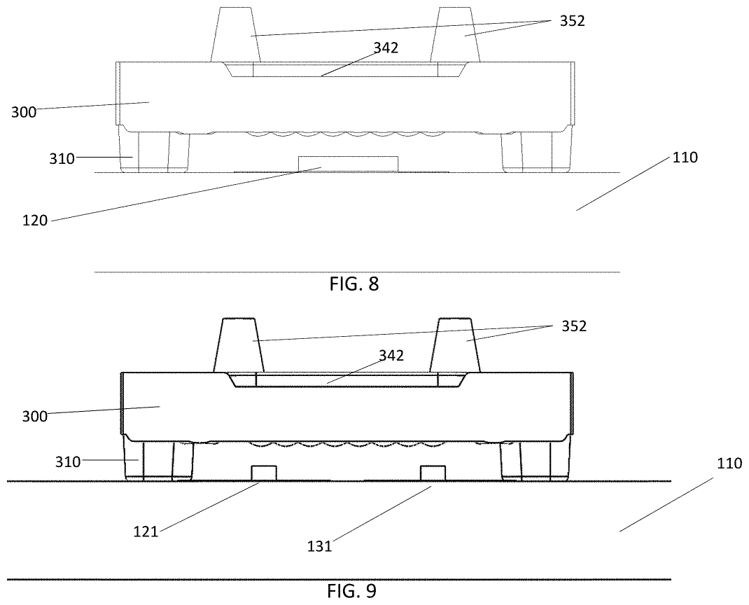

FIG. 8 illustrates optical mount 300 that is positioned at transmit paths of multiple optoelectronic chips 120. The optoelectronic chips 120 are supported by substrate 110. The optical mount 300 is shown as including three legs 310, guide pins 352 and recess 342.

FIG. 9 illustrates optical mount 300 that is positioned at a transmit path of optoelectronic chip 121 and at a receive path of PD 131. The optoelectronic chip 121 and PD 131 are supported by substrate 110. The optical mount 300 is shown as including three legs 310, guide pins 352 and recess 342.

The terms “including”, “comprising”, “having”, “consisting” and “consisting essentially of” are used in an interchangeable manner. For example—any module or chip may include at least the components included in the figures and/or in the specification, only the components included in the figures and/or the specification.

Any reference to the phrases “may” or “may be” should be applied to the phrases “may not” or “may not be”.

The phrase “and/or” means additionally or alternatively.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between blocks are merely illustrative and that alternative embodiments may merge blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. An electro-optic unit, comprising:
a substrate; a
multiple optical engines; each optical engine comprises one or more mechanical housings, each mechanical housing comprises a group of lenses;
multiple electro-optic sub-units, wherein each electro-optic sub-unit is selected out of (a) a transmit electro-optic sub-unit that comprises a group of lasers and a group of at least one laser driver, (b) a receive electro-optic sub-unit that comprises a group of detectors and a group of at least one reception circuits, and (c) a hybrid electro-optic sub-unit that comprises a receive portion and a transmit portion; wherein the transmit portion comprises a sub-group of lasers and a sub-group of at least one laser driver; wherein the receive portion comprises a sub-group of detectors and a sub-group of at least one reception circuits;
wherein at least two electro-optic sub-units are positioned between the substrate and at least two electro-optic sub-units that are associated with the at least two electro-optic sub-units; and
optical conduits that couple the multiple optical engines to at least one out of an optical input of the electro-optic unit and an optical output of the electro-optic unit;
wherein the at least two electro-optic sub-units are not positioned one above the other.

2. The electro-optic unit according to claim 1 wherein the at least two electro-optic sub-units are all of the multiple electro-optic sub-units.

3. The electro-optic unit according to claim 1 wherein the at least two electro-optic sub-units are positioned at substantially a same distance from the substrate.

4. The electro-optic unit according to claim 1 wherein the at least two electro-optic sub-units comprise four electro-optic sub-units.

5. The electro-optic unit according to claim 1 wherein the at least two electro-optic sub-units are arranged as a grid of two by two electro-optic sub-units.

6. The electro-optic unit according to claim 6 wherein the grid comprises two electro-optic sub-units that are transmit electro-optic sub-units and two electro-optic sub-units that are receive electro-optic sub-units.

7. The electro-optic unit according to claim 1 wherein all of the multiple optical engines are positioned at substantially a same distance from the substrate.

8. The electro-optic unit according to claim 1 wherein all of the multiple optical engines comprises transmit electro-optic sub-units.

9. The electro-optic unit according to claim 1 wherein all of the multiple optical engines comprises receive electro-optic sub-units.

10. The electro-optic unit according to claim 1 wherein the multiple optical engines comprise one or more transmit electro-optic sub-units and one or more receive electro-optic sub-units.

11. The electro-optic unit according to claim 1 wherein each optical engine comprises an optical coupler, wherein the one or more mechanical housings comprise (a) a first mechanical housing that belongs to a first portion of the optical coupler, and (b) a second mechanical housing that belongs to a second portion of the optical coupler.

12. The electro-optic unit according to claim 11 wherein the first portion comprises an optical cable interface for receiving a group of optical conduits and three contact elements, each contact element has a spherical surface.

13. The electro-optic unit according to claim 12 wherein the second portion comprises three elongated grooves.

14. The electro-optic unit according to claim 1 wherein each group of lasers comprises eight lasers.

15. The electro-optic unit according to claim 1 wherein each group of detectors comprises eight detectors.

16. The electro-optic unit according to claim 1 wherein a length of the substrate ranges between 50 and 60 millimeters, and a width of the substrate ranges between 14 and 19 millimeters.

17. The electro-optic unit according to claim 1 wherein a length of the substrate is about 55 millimeters, and a width of the substrate is about 16.5 millimeters.

18. The electro-optic unit according to claim 1 wherein a length of an optical engine is about 8.5 millimeters, and a width of the optical engine is about 4.6 millimeters.

19. The electro-optic unit according to claim 1 comprising an optical ferrule that comprises the optical input and the optical output of the transceiver.

20. A method for operating the electro-optic unit of claim 1.
